(19) United States
(12) Patent Application Publication
(10) Pub. No.: US 2012/0049856 A1
(43) Pub. Date: Mar. 1, 2012

(54) PIN TEST ASSISTANT DEVICE AND METHOD FOR USING THE DEVICE

(75) Inventors: GUO-YI CHEN, Shenzhen City (CN); BO TIAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/077,992

(22) Filed: Apr. 1, 2011

(30) Foreign Application Priority Data
Aug. 27, 2010 (CN) 201010264801.0

(51) Int. Cl. B25J 1/00; G01R 31/02

(52) U.S. Cl. 324/537; 294/26

(57) ABSTRACT

A pin test assistant device includes a shaft and a hook. The shaft is made of strong lightweight material that is easily formed into a shaft, and the hook is made of material that resists heat. If a pin on an integrated circuit (IC) chip needs to be tested, the hook is positioned against the underside of the pin, then a heating device is used to heat the pin for softening the pin. After the pin is softened, the hook is used to bend the pin up to for a test of the pin. After the test, the hook is used to press the pin back into an original position.

### BACKGROUND

1. Technical Field

Embodiments of the present disclosure generally relate to testing technology, and more particularly to a pin test assistant device and a method for using the device.

2. Description of Related Art

Integrated circuit (IC) may have a number of pins. During testing of the IC, if there are any problems with signals transmitted in the IC, then a hand tool, such as tweezers, may be used to raise up a suspect pin for examination. Performing such an examination manually is risky because it is difficult to precisely control the strength applied with the hand tool, and damage to the IC or pin is common.

### BRIEF DESCRIPTION OF THE DRAWINGS

FIG. 1 is a front view of one embodiment of a pin test assistant device.

FIG. 2 is diagram illustrating a method for using the pin test assistant device in one embodiment.

FIG. 3 is a flowchart of one embodiment illustrating a method for using the pin test assistant device.

### DETAILED DESCRIPTION

The application is illustrated by way of examples and not by way of limitation in the figures of the accompanying drawings in which like references indicate similar elements. It should be noted that references to “an” or “one” embodiment in this disclosure are not necessarily to the same embodiment, and such references mean at least one.

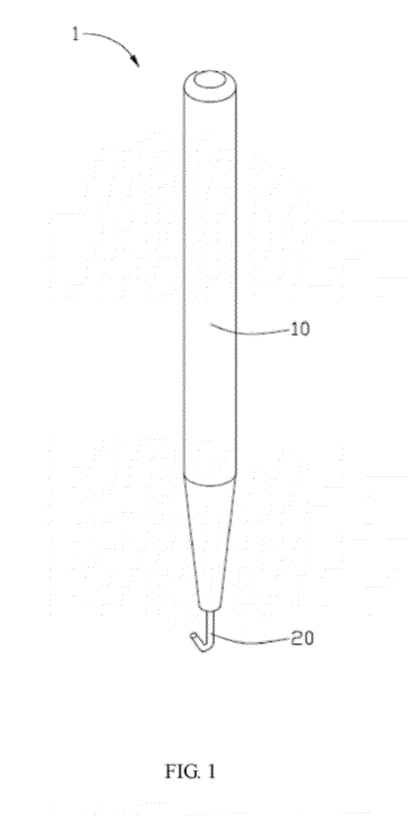

FIG. 1 is a front view of one embodiment of a pin test assistant device 1. In one embodiment, the device 1 includes a shaft 10 and a hook 20. The shaft 10 may be columnar, or any other suitable shape easily held by a test engineer. The shaft 10 may be made of strong lightweight material, such as stainless steel or hard plastics, that is easily formed into a shaft. Size and shape of the hook 20 can be decided according to size and arrangement of pins to be tested. The hook 20 may be made of the same or similar material as the shaft 10 provided the material can resist heat of testing conditions.

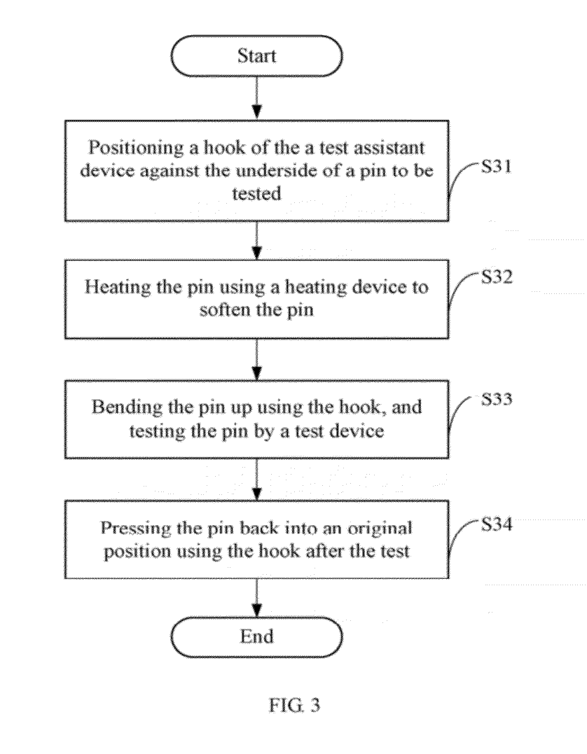

FIG. 3 is a flowchart of one embodiment illustrating a method for using the device 1. To test a pin 301 on an integrated circuit (IC) chip 30, first, an appropriate model of pin test assistant device 1 is selected according to a size of the pin 301 and a distance between the pin 301 and a neighboring pin on the IC chip 30. Depending on the embodiment, additional blocks may be added, others removed, and the ordering of the blocks may be changed.

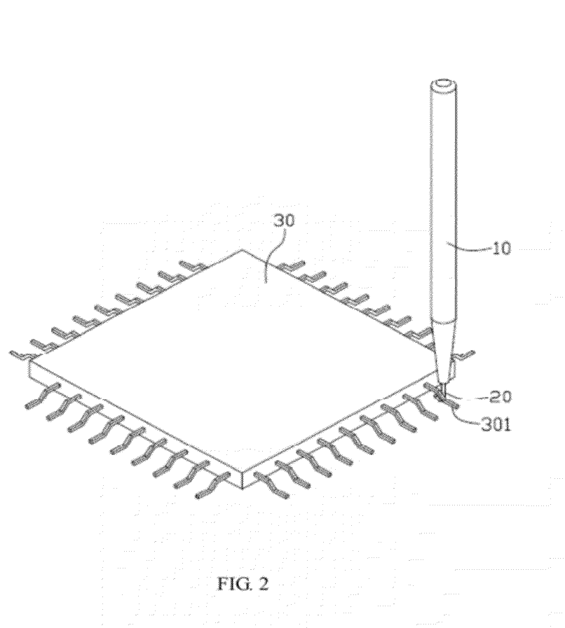

In block S31, as shown in FIG. 2, the hook 20 is positioned against the underside of the pin 301. In block S32, the pin 301 is heated using a heating device, such as an electric iron, to soften the pin 301. After the pin 301 is softened, in block S33, the hook 20 is used to bend the pin 301 up, to be tested by a test device, such as a precision measurement unit (PMU). In one example, if a test signal, such as a reset signal transmitted in the IC chip 30 fails test, then a reset pin on the IC chip is tested.

In block S34, if needed, the pin 301 is reheated after the test, then the pin 301 is pressed back into an original position with, for example, the back of the hook 20.

Although certain inventive embodiments of the present disclosure have been specifically described, the present disclosure is not to be construed as being limited thereto. Various changes or modifications may be made to the present disclosure beyond departing from the scope and spirit of the present disclosure.

What is claimed is:

1. A pin test assistant device comprising a shaft and a hook, wherein the shaft is made of strong lightweight material that is easily formed into a shaft, and the hook is made of material that resists heat.

2. The device as claimed in claim 1, wherein the material is either plastic or stainless steel.

3. The device as claimed in claim 1, wherein size and shape of the hook is decided according to size and arrangement of pins to be tested.

4. A method for using a pin test assistant device, comprising:
positioning a hook of the pin test assistant device against the underside of a pin of an integrated circuit;
heating the pin using a heating device to soften the pin;
bending the pin up using the hook, and testing the pin by a test device; and
pressing the pin back into an original position using the hook after the test.

5. The method as claimed in claim 4, further comprising:
reheating the pin before the pressing step.

6. The method as claimed in claim 4, the hook is made of material that resists heat.

7. The method as claimed in claim 4, wherein the shaft is made of strong lightweight material that is easily formed into a shaft.

8. The method as claimed in claim 7, wherein the material is either plastic or stainless steel.
